(19) United States
(12) Patent Application Publication
(10) Pub. No.: US 2025/0347021 A1
(43) Pub. Date: Nov. 13, 2025

(54) COMPOSITIONS AND METHODS USING HEXAGONAL BORON NITRIDE

(71) Applicant: SAMTEC, INC., New Albany, IN (US)

(72) Inventors: Troy Benton Holland, New Albany, IN (US); Sean Baril, Sherwood, OR (US)

(21) Appl. No.: 19/189,824

(22) Filed: Apr. 25, 2025

Related U.S. Application Data
(60) Provisional application No. 63/639,123, filed on Apr. 26, 2024.

(51) Int. Cl. C25D 5/12; C23C 14/02; C23C 14/06; C23C 14/16; C23C 30/00; C25D 3/12

(52) U.S. Cl. CPC C25D 5/12; C23C 14/021; C23C 14/0647; C23C 14/16; C23C 30/00; C25D 3/12

(57) ABSTRACT

Provided herein are methods and components for increasing the resistance of an electrical component to wear by the inclusion of hexagonal boron nitride (hBN) in coating applications for electronic components. Also provided are electronic components having enhanced wear resistance. The present disclosure also provides dielectric materials that contain hBN structures, as well as components for conducting an electrical signal that contain the inventive dielectric materials.

### CROSS-REFERENCE TO RELATED APPLICATIONS

This application claims the benefit of priority to U.S. Provisional Application No. 63/639,123, filed Apr. 26, 2024, the entire contents of which are incorporated herein by reference.

### TECHNICAL FIELD

The present disclosure concerns the use of boron nitride in electrical applications.

### BACKGROUND

Electrical components such as electrical connectors typically include electrical contacts that mate and unmate with electrical contacts of a complementary electrical component. It is known to coat or plate electrical contacts with precious metal materials due to their high electrical conductivities and resistance to corrosion. These precious metals, and their alloys, include: silver (Ag), gold (Au), palladium (Pd) and platinum (Pt). However, precious metals are also generally prone to rapid wear and have poor response to elevated temperature operations. Wear in metals occurs from sliding surfaces relative to one another abrading, cold-working, and or fatiguing the sliding surfaces. Resistance to wear is achieved by: (1) lowering the modulus of the materials, (2) increasing the hardness of the materials, and/or (3) adding lubricity.

The benefits of increased hardness to wear life is well-established in metals, and the methods by which metal and alloy hardness is increased are also well known. Hardness may be enhanced by alloying, grain size reductions (aka the Hall-Petch relationship), the addition of hard particles, alloying, and work hardening. When hard particles are well-distributed throughout a metal/alloy, with particle diameters at or smaller than the grain sizes of the metal alloy, these particles stabilize the size of those metal/alloy grains. Further, the hard particles stabilize the grain size over larger temperature ranges. It is well known that small grain sizes, in the absence of particles, are prone to grain growth which lowers the hardness of the metal/alloy. Most precious metals are electrodeposited to achieve ultrafine grain (approximately 100-400 nm) or nanograin (<100 nm) sizes with the intent of achieving the highest possible strengths. Unfortunately, this predisposes the plating to loss of hardness when exposed to elevated temperatures, even as low at 100-200° C.

Another way in which wear may be prevented in electrical components is the use of lubricants. In fact, liquid or semi-liquid lubricants are often applied to contacts to help prevent wear and corrosion. However, it is often the case that these lubricants are prone to fouling, thermal degradation, and enhanced wear. The enhanced wear occurs from real-world conditions in which dust and other fine particles get adhered to the liquid lubricant, forming abrasive conditions. Thermal degradation and the limited amount of lubricant, being contained only on the surface of the parts, represent real-world limitations to these lubricants as well. The ideal case would be a thermally stable, electrically non-conductive, and dry lubricant distributed evenly throughout the plating.

Electrical component such as electrical cables include dielectric materials, for example, polymers, that provide electrical insulation to a single electrical conductor in the case of coaxial cables, or a pair of electrical conductors in the case of twinaxial cables. The dielectric materials typically have set operating temperature ratings and mechanical integrity characteristics. When cables are operated at temperatures close to the high end of the temperature rating for the dielectric material in use, polymer degradation can occur, leading to corresponding decrease in electrical performance. Polymers used in cable dielectrics inherently possess relatively low thermal conductivity. Increasing the thermal conductivity of such polymers would result in a broader range of service temperatures for cables utilizing such dielectric materials, thereby increasing the applications and range of conditions under which the cables could be operated.

### SUMMARY

Provided herein are methods for increasing resistance of an electrical component to wear comprising applying a layer of nickel onto a copper-containing portion of the electrical component, and, applying onto the layer of nickel a coating composition that includes nanoparticulate hexagonal boron nitride (hBN) and gold.

Also disclosed are coatings for increasing the wear resistance of an electrical component comprising a layer of nickel, and a layer of composite material comprising nanoparticulate hBN and gold on the layer of nickel.

The present disclosure also provides electrical components having enhanced resistance to wear comprising a copper-containing substrate, a layer of nickel on the copper-containing substrate, and a layer of composite material comprising nanoparticulate hBN and gold on the layer of nickel.

Also provided herein are dielectrics comprising a dielectric polymer and, dispersed within the polymer, hexagonal boron nitride (hBN) structures. The present disclosure also provides components for conducting an electrical signal comprising such dielectrics.

The present disclosure also provides methods for increasing the thermal conductivity of a dielectric comprising dispersing hBN structures within the dielectric material.

Also provided are methods for sending an electronic signal comprising conducting the electronic signal through an electrical component comprising a presently disclosed dielectric.

### BRIEF DESCRIPTION OF THE DRAWINGS

The foregoing summary, as well as the following detailed description of illustrative embodiments of the present application, will be better understood when read in conjunction with the appended drawings. For the purposes of illustrating the locking structures of the present application, there is shown in the drawings illustrative embodiments. It should be understood, however, that the application is not limited to the precise arrangements and instrumentalities shown. In the drawings:

FIG. 1 is a perspective view of an electrical connector constructed in accordance with one example;

FIG. 2 is a perspective view of a printed circuit board in one example having electrical traces, electrical vias, and electrical contact pads adjacent an edge of the printed circuit board;

FIG. 3 is a side elevation view of an electrical component containing hBN in one example;

FIG. 4A is a perspective view of a data communication device constructed as a twinaxial cable, including an inner dielectric that contains hBN in one example;

FIG. 4B is an end elevation view of a data communication device constructed as a coaxial cable, including an inner dielectric that contains hBN in one example;

FIG. 5A is a perspective view of a data communication device constructed as a dielectric waveguide, including an inner dielectric that contains hBN in one example; and

FIG. 5B is an end elevation view of the waveguide illustrated in FIG. 5A.

### DETAILED DESCRIPTION

Aspects of the present disclosure may be understood more readily by reference to the following detailed description taken in connection with the accompanying examples, which form a part of this disclosure. It is to be understood that this invention is not limited to the specific products, methods, conditions or parameters described and/or shown herein, and that the terminology used herein is for the purpose of describing particular embodiments by way of example only and is not intended to be limiting of the claimed invention.

The disclosures of each patent, patent application, and publication cited or described in this document are hereby incorporated herein by reference, in their entirety.

As employed above and throughout the disclosure, the following terms and abbreviations, unless otherwise indicated, shall be understood to have the following meanings.

In the present disclosure the singular forms “a”, “an”, and “the” include the plural reference, and reference to a particular numerical value includes at least that particular value, unless the context clearly indicates otherwise. Thus, for example, a reference to “a compound” is a reference to one or more of such compounds and equivalents thereof known to those skilled in the art, and so forth. Furthermore, when indicating that a certain chemical entity “may be” X, Y, or Z, it is not necessarily intended by such usage to exclude other choices for the entity; for example, a statement to the effect that the chemical entity “may be gold, silver, or palladium” does not necessarily exclude other choices, such as platinum, and the like.

When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” may refer to a value of 7.2 to 8.8,inclusive; as another example, the phrase “about 8%” may refer to a value of 7.2% to 8.8%, inclusive. Also, when the term “about” precedes a range, it is understood that the term modifies both recited endpoints and all points embraced within the range. For example, the phrase “about 1-10” is understood to mean “about 1 to about 10”, as well as “about x”, wherein x refers to any value between 1 and 10. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” In another example, when a listing of possible members including “A, B, and C” is provided, the recited listing may be construed as including situations whereby any of “A, B, and C” is negatively excluded; thus, a recitation of “A, B, and C” may be construed as “A and B, but not C”, or simply “wherein the member is not C”.

As described above, precious metal plating materials are prone to rapid wear and have pore response to elevated temperature operations. Although resistance to wear may be achieved by (1) lowering the modulus of the materials, (2) increasing the hardness of the materials, and/or (3) adding lubricity, efforts to accomplish these objectives have encountered undesirable drawbacks.

The present inventors have surprisingly discovered that use of hexagonal boron nitride (hBN), a stable polymorph of boron nitride (BN), in plating applications successfully targets aforementioned objectives (2) and (3) simultaneously, while also aiding in maintenance of the mechanical, electrical, and chemical properties across a wider temperature range. Thus, when mixed with a metal such as gold, the hBN makes the composition harder (and thus more resistant to wear) and more lubricious. The metal, such as gold, can be porous, and the hBN can be disposed in the pores, thereby preventing the grain size of the metal from increasing with elevated temperatures. Further, because the hBN is disposed in the pores, the hBN has a negligible if any effect on the conductivity of the metal. Thus, the volume percentage of hBN can be set to an amount that at least partially or substantially fills the pores, but not so much that it more than minimally mixes with the metal outside the pores to the extent that it would have a substantial impact on electrical conductivity.

Hexagonal boron nitride further exhibits lubricious properties due to its two-dimensional, graphite-like structure. The boron and nitrogen atoms are arranged in hexagonal cells to form sheets of hBN that are bonded with lower strength van der Waals bonds between the sheets, and so the strong sheets easily exfoliate and provide a means of dry lubrication. These exfoliated sheets are also non-conductive and essentially inert. Particles of hBN can be produced at many length scales down to the nanometric which then are often referred to as boron nitride nanosheets (BNNS).

It has presently been found that hBN and/or BNNS functions as a thermally stable, electrically non-conductive, and dry lubricant that can be distributed throughout plating material. For instance, the hBN and/or BNNS can be distributed substantially evenly throughout plating material. Another benefit of using hBN and/or BNNS reinforcement as described herein is that the particles are chemically and electrochemically inert with respect to the metals. In contrast, an electrically conductive particle would cause increased galvanic corrosion by providing a local electron path to create a galvanic cell. Further, most electrically conductive particles would also be galvanically coupled to the metal which would: (1) galvanically etch out the particle which would leave pores and lessened lubricity; or (2) galvanically attack the precious metal causing rapid corrosion and likely removal of the lubricious particles themselves. Another benefit of the use of non-electrically conductive hBN and/or BNNS is that the debris caused by wear does not risk creating electrical shorts between adjacent contacts.

Accordingly, provided herein are methods for increasing wear resistance of an electrical component comprising the steps of applying a layer of nickel onto a copper-containing portion of the electrical component, and, applying onto the layer of nickel a coating composition that includes nanoparticulate hexagonal boron nitride (hBN) and gold. In one example, the hBN can be present as nanotubes of hBN, also known as white graphene. The gold in the coating composition may be provided as elemental gold, or an alloy with another metal species. Exemplary alloying species include iron, nickel, and cobalt.

In certain embodiments, the coating composition can include one or more other precious metals in place of at least a portion up to all of the gold. For example, one or more other precious metals can be silver, platinum, palladium, rhodium, ruthenium, iridium, osmium, or any combination thereof. In this way, the coating composition and the layer that is produced using the coating composition may contain one or more additional or other precious metal species. Accordingly, reference to “metal” in the present disclosure with respect to the coating composition can refer to any one of or more of the alternative metals listed above, such as a precious metal, alloys thereof, or may refer only to gold.

The electrical component may be any part of an electrical device or system that benefits from high electrical conductivity with resistance to corrosion, wear, abrasion, and/or thermal degradation. The coating composition can be disposed on at least a portion of the electrical component. For instance, the coating composition can be on a portion of the electrical component that wipes against or otherwise contacts a complementary electrical component to establish an electrical connection between the electrical component and the complementary electrical component. In another example, the coating composition can be disposed on an entirety of the electrical component. Thus, it can be said that at least a portion of the electrical component comprises the coating composition.

Referring now to FIG. 1, in some embodiments, the electrical component 20 can be configured as an electrical contact 22 of an electrical connector 24. The electrical connector 24 can include an electrically insulative connector housing 26 and a plurality of the electrical contacts 22 that are supported by the connector housing 26. The electrical contacts 22 can be arranged in one or more rows as desired. In one example, the electrical contacts 22 can be supported by respective leadframe housings 28 to define respective leadframe assemblies 30. For instance, the electrical contacts 22 can be insert molded in the leadframe housings 28, or can be stitched into the leadframe housings 28. In other examples, the electrical contacts 22 can be supported directly by the connector housing 26. The electrical contacts 22 each defines a mating portion 23 that is wiped against a complementary electrical contact of a complementary electrical device when the electrical connector 24 is mated with the complementary electrical device. The complementary electrical device can be configured as a complementary electrical connector or a substrate such as an edge card. The electrical contacts 22 each further defines a mounting portion 25 opposite the mating portion 23 that is configured to be mounted to a complementary electrical device, such as a substrate that can be configured as a printed circuit board. The mounting portions 25 can be configured to be inserted into a plated through-hole or via of an underlying substrate, such as eye-of-the-needle (EON). Alternatively, the mounting portions 25 can be configured to be surface mounted onto electrical pads of the underlying substrate. The electrical contacts 22 can be configured as pre-assigned electrical signal contacts or pre-assigned electrical ground contacts. Adjacent ones of the signal contacts, for instance along a given row, can define differential signal pairs, or the signal contacts can alternatively be single-ended. The electrical connector 24 can include one or more grounds between adjacent pairs of signal contacts along a given row. Alternatively the electrical connector 24 can define an open pin field of unassigned electrical contacts that become signal or ground contacts during use. While the coating composition can be defined at the mating portion 25, it should be appreciated that the coating composition can alternatively or additionally be defined at any location of the electrical contact 22, such as at the mounting portion 25. The coating composition can be defined by at least a portion up to an entirety of the electrical contact 22. While the electrical connector 24 is illustrated in accordance with one example, it is recognized that electrical connectors 24 can have different configurations, and the present disclosure contemplates all such configurations. In one example, the electrical connector 24 can be an electrical power connector, and the electrical contacts 22 can be configured to carry electrical power greater than one volt.

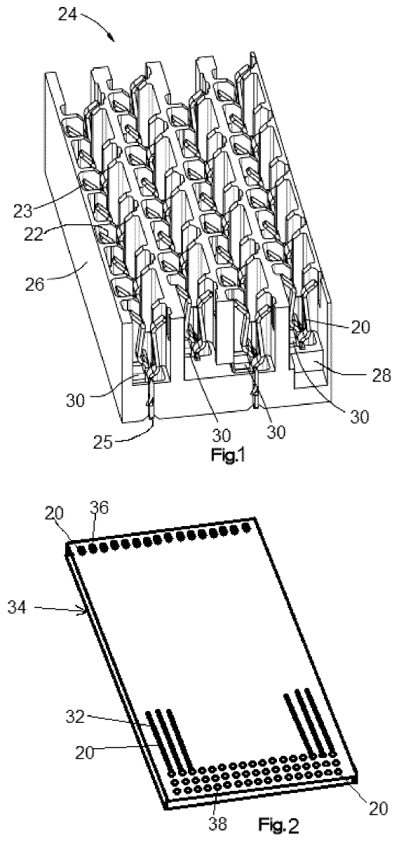

Referring now to FIG. 2, the electrical component 20 can be configured as an electrical trace 32 of a substrate 34, an electrical contact pad 36 of the substrate 34 or other surface mount technology (SM T) electrical apparatus of a substrate, an electrically conductive via 38 of the substrate 34, or any alternative suitable electrically connective element as desired. In some examples, the substrate 34 can be configured as a printed circuit board, which can define a rigid board or a flex circuit as desired. As shown in FIG. 2B, the rigid board can be configured as an edge card in some examples having electrical contact pads adjacent the edge of the substrate and configured for insertion between the mating ends of adjacent rows of electrical contacts of an electrical connector.

Referring now to FIG. 3, the electrical component 20 can include a substrate layer 40 that can be formed from any suitable electrically conductive material. In one example a copper-containing layer can define the substrate layer 40. As used herein, “copper-containing” can refer to aspects of the electrical component that include elemental copper, commercially pure copper, a mixture of copper with another element or compound (e.g., beryllium-copper), or an alloy of copper with another element, such as another metal.

The electrical component 20 can further include a barrier layer 42 disposed on the substrate layer 40. Thus, in one example, no other layers are disposed between the barrier layer 42 and the substrate layer 40. In particular, the barrier layer 42 can define a first surface 42a that faces the substrate layer 40, and a second surface 42b opposite the first surface 42a and faces away from the substrate layer 40. In one example, a nickel-containing layer can define the barrier layer 42. As used herein, “nickel-containing” can refer to aspects of the electrical component that include elemental nickel, a mixture of nickel with another element or compound, or an alloy of nickel with another element, such as nickel phosphorous (NiP), palladium nickel (PdNi), or an alloy of nickel with another metal. The step of applying the barrier layer 42 to the substrate layer 40 can include any known industrial process, such as by electroplating, mechanical deposition, or physical vapor deposition. For example, when the barrier layer 42 is a nickel-containing layer, the application of the barrier layer 42 may include the use of nickel sulfamate, Wood's nickel, Watt's nickel, or the like during electroplating, mechanical deposition, or physical vapor deposition.

In some examples, the substrate layer 40 can be cleaned prior to application of the barrier layer 42 onto the substrate layer 40. The cleaning may include any standard industrial cleaning process for metal surfaces. Standard cleaning processes can involve the use of sodium hydroxide, and optionally one or more wetting agents to remove oil, dirt, and other surface contamination. The substrate layer 40 may additionally or alternatively be activated prior to application of the barrier layer 42 onto the substrate layer 40. In one example, the activation step can be performed after the cleaning step. Activation can involve applying an acid or acidic solution to the substrate layer 40. An exemplary cleaning solution can contain 10% of a mineral acid, such as sulfuric acid. In some embodiments, activation includes applying voltage to the substrate 40 in the positive direction, the negative direction, or both.

The electrical component 20 can further include a coating 44 that is disposed on the barrier layer 42, such that the barrier layer 42 is disposed between the substrate layer 40 and the coating 44. In particular, the coating 44 can define a respective first surface 44a that faces the second surface 42b of the barrier layer 42, and a respective second surface 44b that is opposite the first surface 44a. The second surface 44b of the coating 44 can define the outer surface of the electrical component 20. The coating 44 can be defined by the coating composition that includes the metal and nanoparticulate hexagonal boron nitride (hBN) as described above. It should be appreciated that the barrier layer 42 defines a mechanical barrier between the substrate layer 40 and the coating 44. The barrier layer 42 can also provide a diffusion barrier that prevents the copper from the substrate layer 40 from diffusing into the metal of the coating 44. In other examples, the electrical component can be devoid of the substrate layer 40.

The barrier layer 42 can have any suitable thickness as desired as defined from the first surface 42a to the second surface 42b. Similarly, the coating 44 can have any suitable thickness as desired as defined from the first surface 44a to the second surface 44b. In one example, the thickness of the coating 44 is less than the thickness of the barrier layer 42. For instance, the thickness of the coating 44 can be between in a range from about 5% to about 50% of the thickness of the barrier layer 42, such as from about 10% to about 40% of the thickness of the barrier layer 42, such as from about 20% to about 25% of the thickness of the barrier layer 42. In one specific example, the thickness of the barrier layer 42 can be in a range from about 2 82 m to about 10 82 m, such as from about 3 82 m to about 7 82 m, and in one example from about 3.5 82 m to about 5 82 m, such as about 4 82 m. The thickness of the coating 44 can be as desired, such as from about 0.25 82 m to about 3 82 m, such as from about 0.5 82 m to about 2 82 m, and in one specific example from about 0.75 82 m to about 1 82 m.

The step of applying the coating composition to the barrier layer 42 may include electroplating, mechanical deposition, or physical vapor deposition. In a one example, the coating composition can be applied to the barrier layer 42 by placing at least the surface 42b of the barrier layer 42 to be coated into a bath containing the hBN nanoparticles and gold solution, and by applying an electrical current to induce deposition the coating composition onto the barrier layer 42. For example, the electrical current may be a DC current of about 5-20 amps per square foot (ASF). A functionalizer or dispersant can be added to cause the hBN to suitably mix in the metal.

The coating composition can include hBN in an amount that is in a range from about 1 vol % hBN to about 15 vol % hBN. For example, the coating composition may comprise about 1 vol % hBN, about 2 vol % hBN, about 3 vol % hBN, about 4 vol % hBN, about 5 vol % hBN, about 6 vol % hBN, about 7 vol % hBN, about 8 vol % hBN, about 9 vol % hBN, about 10 vol % hBN, about 11 vol % hBN, about 12 vol % hBN, about 13 vol % hBN, about 14 vol % hBN, or about 15 vol % hBN. It has been found that quantities of hBN greater than 15 vol % can begin to adversely impact electrical conductivity. In one example, the hBN can be present in a range from about 1 vol % hBN to about 5 vol % hBN. In another example, the hBN can be present in a rage from about 10 vol % hBN to about 12 vol % hBN. In still another example, the hBN can be present in a range from about 5 vol % hBN to about 10 vol % hBN.

The balance of the coating composition can be defined by electrically conductive material. Thus, electrically conductive material can be present in an amount that is in a range from about 85 vol % to about 99 vol %, such as from about 90 vol % to about 95 vol %. In one example, the electrically conductive material can be gold. For instance, the gold can be a cobalt-hardened gold. It should be appreciated that other golds and other electrically conductive material, alone or in combination, are contemplated.

The coating composition may have a hardness in a range from about 100 HV to about 300 HV, such as about 100 HV, about 110 HV, about 120 HV, about 130 HV, about 140 HV, about 150 HV, about 160 HV, about 170 HV, about 180 HV, about 190 HV, about 200 HV, about 210 HV, about 220 HV, about 230 HV, about 240 HV, about 250 HV, about 260 HV, about 270 HV, about 280 HV, about 290 HV, or about 300 HV. In preferred embodiments, the coating composition retains these hardness characteristics during exposure to temperatures up to about 200° C. For example, the present coatings may have a hardness of from 100 HV to 300 HV following exposure to a temperature of up to about 200° C. for about 1-24 hours.

The term “about,” “substantially,” “approximately,” derivatives thereof, and words of similar import, when used to described amounts, sizes, shapes, spatial relationships, distances, directions, and other similar parameters includes the stated parameter in addition to a range up to 10% more and up to 10% less than the stated parameter, including up to 9% more and up to 9% less, including up to 8% more and up to 8% less, including up to 7% more and up to 7% less, including up to 6% more and up to 6% less, including up to 5% more and up to 5% less, including up to 4% more and up to 4% less, including up to 3% more and up to 3% less, including up to 2% more and up to 2% less, including up to 1% more and up to 1% less.

Once applied, the coating composition represents a layer of hBN and gold on the layer of nickel. The average thickness of the layer of hBN and gold may be about 0.1 to 1.5 μm. For example, the layer of hBN and gold may have an average thickness in a range from about 0.1 82 m to about 1.5 82 m, such as about 0.1 82 m, about 0.2 82 m, about 0.3 82 m, about 0.4 82 m, about 0.5 82 m, about 0.6 82 m, about 0.7 82 m, about 0.8 82 m, about 0.9 82 m, about 1.0 82 m, about 1.1 82 m, about 1.2 82 m, about 1.3 82 m, about 1.4 82 m, or about 1.5 82 m.

In some examples, the barrier layer 42 can also include hBN, which can prevent copper of the substrate layer 40 from leaching the metal of the coating 44 off the surface of the barrier layer 42 that supports the coating 44. The hBN can be incorporated into the barrier layer 42 as described above with respect to the coating 44. Thus, a functionalizer or dispersant can be added to cause the hBN to suitably mix in the metal of the barrier layer. It has been found that the quantity of hBN can be sufficiently low while still preventing the leaching while at the same time not sacrificing electrical conductivity of the barrier layer 42. Thus, the electrical component can be a signal or ground contact, or can also be an electrical power contact. When hBN is present in both the barrier layer 42 and the coating 44, the particle size of the hBN in the coating 44 is less than the particle size of the hBN in the barrier layer 42. The hBN coating can be present in the same volume percentages described above with respect to the coating that includes hBN and gold.

It should be appreciated that the substrate 40 and the barrier layer 42 combine to define an electrically conductive body 46, and the electrical component 20 further includes the coating composition disposed on the body as described herein. However, it should be appreciated that the electrically conductive body 46 can be alternatively constructed. For instance, the electrically conductive body 46 can include a single metal-containing layer configured as the substrate 40, the barrier layer 42 as described above, or other metal-containing layer. Alternatively, the electrically conductive body 46 can include multiple metal-containing or otherwise electrically conductive layers, any or all of which or none of which are configured as the substrate 40 or the barrier layer 42 as described above. Thus, it can be said that the electrically conductive body 46 includes at least one metal-containing layer or at least one otherwise electrically conductive layer. The electrically conductive body 46 can further include any additional layers as desired, whether electrically conductive or electrically insulative.

In one specific example, coatings are provided for increasing the wear resistance of an electrical component comprising a first layer that can include nickel or any of the alternative materials of the barrier layer 42 described above, and a coating layer of composite material comprising nanoparticulate hBN and metal, such as precious metal, disposed on the layer of nickel.

Also provided herein are compounds or dispersions containing hexagonal boron nitride where graphite would conventionally be used. Thus, in accordance with the present disclosure, graphite-containing compounds or solutions or dispersions can be substituted with hexagonal boron nitride. For example, graphite can be substituted with hexagonal boron nitride in the ARGUNA C-100 silver-graphite dispersion electrolyte, commercially available from UMICORE having a principal place of business in Brussels, Belgium.

Also provided herein are electrical components having enhanced resistance to wear comprising a copper-containing substrate that can be constructed as described above with respect to the substrate 40, and a coating on the substrate that can be constructed as the coating composition as described above. The electrical components may be, for example, electrical contacts, electrical traces or vias of a printed circuit board or a flexible circuit, or electrical traces of an edge card.

The present disclosure also pertains to dielectric or electrically insulative materials. Electrical components, such as coaxial cables, that contain dielectric materials, have service temperatures that depend in part on the characteristics of the polymer(s) that form the dielectric. As the amount of power translated through a cable increases over time, the cable is heated, and can approach the temperature at which the dielectric material can begin to degrade, at which point the electrical performance of the cable decreases. The present inventors have surprisingly discovered that, despite the expectation that they would cause electrical interference with the signal being conducted, hexagonal boron nitride (hBN) nanostructures function to stabilize the impedance of a dielectric into which the hBN structures are incorporated. In particular, hBN structures are not uniformly and repeatably oriented, positioned, concentrated, or patterned in the dielectric, which would be expected to cause impedance mismatches along the signal transmission path. The hBN structures in one form can be commercially available as Boron Nitride NanoBarbs™ commercially available from BNNano, Inc., having a principal place of business in Cary, NC. In other examples, the hBN structures can be configured as hBN nanotubes. Thus, the hBN structures can be hBN nanostructures. The hBN structures can be produced by growing hexagonal boron nitride nano-crystals on the outside surface of nanotubes. At the same time, it has been found that hBN structures increase the service temperature of dielectrics, and thereby the electrical components containing the materials.

Accordingly, provided herein are dielectrics comprising a dielectric material and hexagonal boron nitride (hBN) structures dispersed within the dielectric material. The dielectric material may be any material or composition that is suitable for dielectric applications. In some embodiments, the dielectric material is a polymer or combination of polymers. For example, the dielectric material may be a thermoplastic polymer. In some embodiments, the dielectric material is a fluoropolymer, such as fluorinated ethylene-propylene (FEP), a perfluoroalkoxy alkane (PFA), polytetrafluoroethylene (PTFE), polyvinylfluoride (PVF), polyvinylidene fluoride (PVDF), polychlorotrifluoroethylene (PCTFE), polyethylenetetrafluoroethylene (ETFE), polyethylenechlorotrifluoroethylene (ECTFE), perfluoropolyether (PFPE), Perfluorosulfonic acid (PFSA-Nafion), or any combination thereof. In other embodiments, the dielectric material comprises a non-fluoropolymer, of which polypropylene (PP), polyethylene (PE), or any combination thereof represent examples.

The hBN structures are dispersed within the dielectric material, preferably in an amount of about 0.5-15 wt %, based on the total weight of the dielectric. For example, the amount of the hBN structures that are dispersed within the dielectric material may be about 0.5, 1, 1.5, 2, 2.5, 3, 3.5, 4, 4.5, 5, 5.5, 6, 6.5, 7, 7.5, 8, 8.5, 9, 9.5, 10, 10.5, 11, 11.5, 12, 12.5, 13, 13.5, 14, 14.5, or 15 wt %, based on the total weight of the dielectric.

Dispersal of the hBN structures within the dielectric material may be performed in any suitable manner, such as by adding the hBN structures to the dielectric material when the latter is in a molten or otherwise fluid state, followed by mixing to a sufficient degree to achieve substantially uniform dispersal of the hBN structures within the dielectric material to create a composite dielectric. Mixing may be performed using standard industrial techniques. The resulting composite dielectric can be processed for use in a data communication device, such as by extruding the dielectric composite dielectric.

Also provided herein are methods for increasing the thermal conductivity of a dielectric of a data communication device. The methods can include the step of dispersing hBN structures within the dielectric material of the dielectric. As described above, dispersal of the hBN structures within the dielectric material may be performed in any suitable manner. The hBN structures can be micron or sub-micron sized that can create a network of interconnected web of the hBN structures. The hBN structures can have different sizes and shapes as desired. The hBN structures are configured to absorb radiation, such that the data communication device can withstand a higher doses of radiation in space with the hBN structures compared to an identical data communication device, but without the hBN structures.

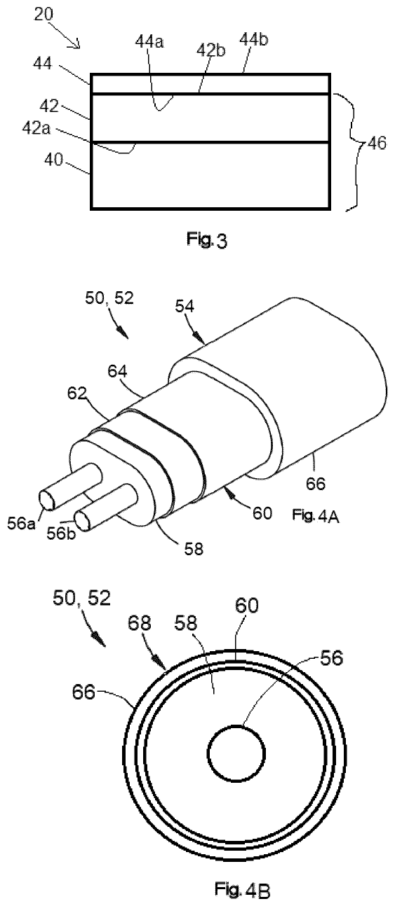

The present disclosure also provides data communication devices for conducting an electrical signal comprising a dielectric that can be configured as a composite dielectric according to any of the preceding embodiments. For example, as illustrated in FIGS. 4A-4B,, the data communication device 50 may can be configured as a cable, such as an electrical cable 52 that can be a radio frequency (RF cable) or any suitable alternative electrical cable. In one example shown in FIG. 4A, the electrical cable 52 can be configured as a twinaxial cable 54. The twinaxial cable 54 includes a pair of first and second electrical conductors 56a and 56b that are each surrounded by the dielectric 58 including hBN as described herein. The electrical conductors 56a and 56b are configured to transmit electrical signals, and thus can be referred to as electrical signal conductors. The twinaxial cable 54 includes an electrical shield 60 that surrounds the dielectric 58 and provides electrical shielding to the electrical conductor. The electrical shield 60 can include a single layer, or can include first and second layers 62 and 64. The single layer can be configured as an electrically conductive foil, film, or braid. First and second layers 62 and 64 be selected as different ones of an electrically conductive foil, film or braid. The twinaxial cable 54 can further include an outer electrically insulative jacket 66 that surrounds the electrical shield 60 Referring now to FIG. 4B in particular, the electrical cable 52 can be configured as a coaxial cable 68 which can be constructed as described above with respect to the twinaxial cable 54, except the coaxial cable 68 includes a single electrical conductor 56 that are each surrounded by the dielectric 58. Further, the dielectric 58, the shield 60, and the outer jacket 66 of the coaxial cable 68 can be substantially circular in shape, and substantially oval in shape when the electrical cable 52 is a twinaxial cable 54.

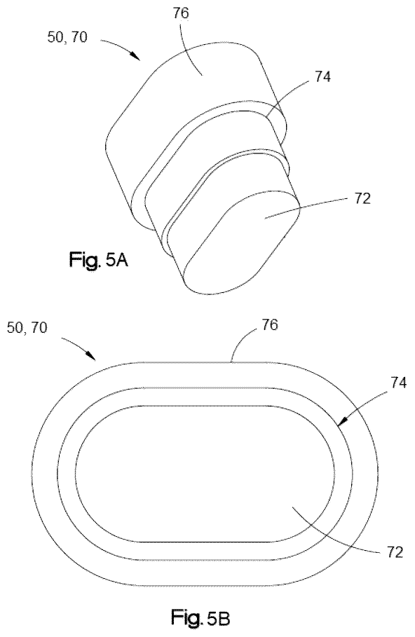

In still other examples, referring now to FIG. 5A-5B, the data communication device 50 can be configured as a cable configured as a waveguide 70. In some examples, the waveguide 70 can be configured to propagate RF electrical signals, and can be referred to as a RF waveguide. The waveguide 70 includes an inner dielectric 72 that can include hBN in the manner described herein, and an electrical shield 74 that surrounds the inner dielectric 72. The waveguide 70 can include an outer electrically insulative jacket 76 that surrounds the electrical shield 74. The waveguide 70 can be devoid of an electrical conductor disposed within the electrical shield 74.

It should be appreciated that a data communication assembly can include the electrical connector 22 described above, the substrate 34 in the form of a printed circuit board to which the electrical connector can be mounted, the substrate 34 in the form of an edge card that can be mated with the electrical connector 22, and/or a plurality of data communication devices 50 that can be mounted to the electrical connector 22. For instance, the electrical signal conductors of the electrical cable can be mounted to respective ones of the electrical contacts of the electrical connector. Thus, the electrical connector 22 can facilitate communication between the data communication device and the substrate.

In the context of a RF cable, it is recognized that RF power through the cable in certain decibel and frequency ranges can increase the temperature of the cable. Thus, temperature can be a limiting factor during operation of conventional RF cables. By increasing the thermal conductivity of the dielectric, the resulting data communication device can operate at higher temperatures than conventional data communication devices.

Further, it is believed that the cable with the dielectric including hBN as described herein can be operable at temperatures above 260 degrees C., for instance up to approximately 300 degrees C., which is an improvement over conventional cables whose operating temperatures are limited because the hBN can keep reduce or prevent creep or deformation of either or both of the outer dielectric jacket or the inner dielectric 58. It is believed that when the dielectric of the cable includes hBN, the hBN can function as a mechanical stiffener in the dielectric.

The present disclosure also pertains to methods for sending an electronic signal comprising conducting the electronic signal through an electrical component of a data communication device that also comprises the dielectric according to any one of the embodiments disclosed herein. The electrical component may be, for example, defined by the electrical signal conductors of the coaxial cable and twinaxial cable. In particular, the electrical signal conductors of the coaxial cable and twinaxial can include the hBN-containing coating composition in the manner described above.

### EXAMPLES

Aspects of the present disclosure are further defined in the following examples. It should be understood that these examples, while indicating preferred embodiments of the invention, are given by way of illustration only, and should not be construed as limiting the appended claims. From the above discussion and these examples, one skilled in the art can ascertain the essential characteristics of this invention, and without departing from the spirit and scope thereof, can make various changes and modifications of the invention to adapt it to various usages and conditions.

### Example 1—Preparation of Coating For Increasing Wear Resistance

An acid citrate gold composition is formulated with gold using: potassium gold cyanide in a concentration of four to 12 g/L; citric acid in a concentration of 20 to 70 g/L; potassium citrate in a concentration of 50 to 90 g/L; and, an alloying element comprising iron, nickel, cobalt, or another metal in a concentration of about 1-3 g/L.

To the resulting bath is added nanogranular (<100 nm) hBN particles. The particles are optionally provided as a dispersal of the particles in a solution using a dispersant, functionalize, or both, and may have been subjected to sonication, ultrasonication, and or other agitation/activation.

The pH of the bath is adjusted to between 3 and 4, followed by heating the bath to between 30-35° C. A DC current of about 5-20 amps per square foot (ASF) is used to co-deposit the gold alloy with encapsulated hBN nanoparticles as a coating onto a nickel-coated copper substrate.

The thickness of the gold/hBN coating is 5-30 microinches (0.1-1.27 μm). The resulting hardness is about 100-300 HV.

### Example 2—Dielectric

To 95 g of perfluoroalkoxy alkane (PFA) dielectric polymer is added 5 g of hexagonal boron nitride (hBN) nanobarbs. The combination is mixed using an industrial paddle mixer for 15 minutes. The mixed combination is melt-extruded to form a dielectric that surrounds an electrical conductor.

1. A coating configured to increase wear resistance and lubricity of an electrical component having an electrically conductive body, the coating comprising a composite material that includes nanoparticulate hBN and a metal, wherein the composite material is disposed on the electrically conductive body.

2. The coating according to claim 1, wherein the electrically conductive body comprises a nickel-containing layer, and the coating is disposed on the nickel-containing layer.

3. The coating according to claim 2, wherein the electrically conductive body further comprises a substrate.

4. The coating according to claim 3, wherein the substrate comprises copper.

5. (canceled)

6. The coating according to claim 2, wherein the nickel-containing layer has a thickness of about 2 μm to about 10 82 m.

7. (canceled)

8. The coating according to claim 6, wherein the composite material defines a layer having a thickness of about 0.25 82 m to about 3 82 m.

9. (canceled)

10. The coating according to claim 1, wherein the hBN is disposed in pores defined by the metal.

11. The coating according to claim 10, wherein the metal is a precious metal.

12. (canceled)

13. The coating according to claim 1, wherein the composite material comprises about 1 to about 15 vol % hBN.

14. The coating according to claim 1, wherein the composite material comprises gold in an amount that is in a range from about 85 vol % to about 99 vol %.

15. (canceled)

16. (canceled)

17. (canceled)

18. (canceled)

19. (canceled)

20. (canceled)

21. (canceled)

22. (canceled)

23. (canceled)

24. A method for increasing resistance of an electrical component to wear comprising:
applying a first electrically conductive layer onto an electrically conductive substrate; and
applying coating composition onto the first electrically conductive layer, wherein the coating composition includes nanoparticulate hexagonal boron nitride (hBN) and a metal.

25. The method according to claim 24, wherein the electrically conductive substrate comprises a copper-containing material.

26. (canceled)

27. (canceled)

28. The method according to claim 25, wherein the copper-containing material is activated prior to application of the layer of nickel.

29. The method according to claim 28, wherein the copper-containing material is activated using an acidic solution.

30. (canceled)

31. (canceled)

32. The method according to claim 24, wherein the first electrically conductive layer comprises a nickel-containing material

33. The method according to claim 24, wherein the metal is a precious metal

34. (canceled)

35. (canceled)

36. The method according to claim 24, wherein the coating composition comprises about 1 to 15 vol % hBN.

37. (canceled)

38. A dielectric comprising a dielectric material and, dispersed within the material, hexagonal boron nitride (hBN) structures.

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. A method for making the dielectric according to claim 38 comprising dispersing the hBN structures within the dielectric material.

51. The method according to claim 50, wherein the hBN structures are dispersed within the dielectric material in an amount of about 0.5-15 wt %, based on the total weight of the dielectric.

52. (canceled)

53. (canceled)

54. (canceled)

55. (canceled)

56. (canceled)

57. (canceled)
